(19) United States
(12) Patent Application Publication
(10) Pub. No.: US 2022/0344555 A1
(43) Pub. Date: Oct. 27, 2022

(54) DISPLAY BACKPLANE, DISPLAY DEVICE AND TILED DISPLAY DEVICE

(71) Applicant: Chongqing Konka Photoelectric Technology Research Institute Co., LTD., Chongqing (CN)

(72) Inventors: Ying Qi Wang, Chongqing (CN); Pofu Chen, Chongqing (CN); Jiang Cao, Chongqing (CN); Cheng Ming Liu, Chongqing (CN)

(21) Appl. No.: 17/256,580

(22) PCT Filed: Feb. 20, 2020
(86) PCT No.: PCT/CN2020/076062

§ 371 Date: Dec. 28, 2020

(30) Foreign Application Priority Data
Jan. 16, 2020 (CN) 202010049559.9

(51) Int. Cl. H01L 33/62; G09F 9/302; G09F 9/33; H01L 27/15

(52) U.S. Cl. CPC H01L 33/62; G09F 9/3026; G09F 9/33; H01L 27/156

(57) ABSTRACT

Disclosed is a display backplane, comprising a backplane, micro light-emitting diodes, a plug-in circuit board, and signal lines; a light-emitting area arranged on front surface of the backplane; a first trace area and a second trace area arranged on both opposite sides of the light-emitting area, and a third trace area arranged on one side of the light-emitting area and between the opposite sides; the third trace area is arranged between the first trace area and the second trace area; first signal lines are routed from the first trace area and the second trace area and are electrically coupled to the plug-in circuit board through the third trace area, second signal lines routed along the back surface from the first trace area and the second trace area are arranged on the third trace area in a winding manner. A display device and a tiled display device are also disclosed.

### TECHNICAL FIELD

The present disclosure relates to displays, in particular to display backplanes, display devices and tiled display devices.

### BACKGROUND OF THE INVENTION

The backplane of an LED display conventionally includes several pixel areas, in which each pixel point contains a red LED, a blue LED and a green LED. Such RGB pixel areas constitute a display area; and both sides outside the display area are boundary regions. However, the boundary of the display may be wider due to a larger width of each boundary region caused by each individually current-driven LED and thousands of data lines.

Further, the tiling effect of the displays may be affected by their boundary, thereby affecting the display effect.

### SUMMARY OF THE INVENTION

For this purpose, a display backplane, a display device and a tiled display device, which can reduce the boundary of the device and better the display effect thereof, may be necessarily provided.

The object is satisfied by the technical solution of the present disclosure which is as follows:

In a first aspect, a display backplane is provided in the present disclosure. The display backplane may include a backplane, a plurality of micro light-emitting diodes arranged on the backplane in a matrix structure, a plug-in circuit board arranged on one end of the backplane, and a plurality of signal lines electrically connected to the plurality of micro light-emitting diodes in a one-to-one correspondence and to the plug-in circuit board, wherein the backplane comprises a front surface and a back surface opposite to the front surface; a light-emitting area provided with the plurality of micro light-emitting diodes and arranged on the front surface; a first trace area and a second trace area arranged on both opposite sides of the light-emitting area, and a third trace area arranged on one side of the light-emitting area and between the opposite sides; the third trace area is arranged between the first trace area and the second trace area; the plurality of the signal lines comprises first signal lines and second signal lines; the first signal lines are routed from the first trace area and the second trace area and are electrically coupled to the plug-in circuit board through the third trace area, the second signal lines routed along the back surface from the first trace area and the second trace area are arranged on the third trace area in a winding manner, and are routed from the third trace area and electrically coupled to the plug-in circuit board.

In a second aspect, the present disclosure provides a display device which may include a housing and the above-mentioned display backplane arranged in the housing.

In a third aspect, the present disclosure provides a tiled display device which may include a housing and a plurality of the above-mentioned display backplanes arranged in the housing, wherein the plurality of display backplanes are spliced together.

With the above display backplane, display device and tiled display device, since the first signal lines is routed from the first trace area and the second trace area and is electrically connected to the plug-in circuit board, the second signal lines are routed from the first trace area and the second trace area to be arranged on the third trace area in a winding manner along the back surface.

### BRIEF DESCRIPTION OF THE DRAWINGS

The exemplary embodiments of the present disclosure will be described in detail with reference to the accompanying drawings to make the aforesaid features and advantages of the present disclosure more clear to those skilled in the art. There are shown in the drawings:

FIG. 1 is a schematic diagram of a display backplane in accordance with a first embodiment of the present disclosure;

FIG. 2 is a schematic diagram of a display backplane in accordance with a second embodiment of the present disclosure;

FIG. 3 is a schematic diagram of a display backplane in accordance with a third embodiment of the present disclosure;

FIG. 4 is a schematic diagram of a display backplane in accordance with a fourth embodiment of the present disclosure;

FIG. 5 is a schematic diagram of a display backplane in accordance with a fifth embodiment of the present disclosure;

FIG. 6 is a schematic diagram of a display backplane in accordance with a sixth embodiment of the present disclosure;

FIG. 7 is a schematic diagram of a display device having the display backplane shown in the first embodiment of the present disclosure; and

FIG. 8 is a schematic diagram of a tiled display device having the display device shown in FIG. 7.

### DETAILED DESCRIPTION

The present disclosure is set forth in a detailed description accompanied with the drawings to provide a clearer and more accurate understanding. Exemplary embodiments of the present disclosure are illustrated in the Drawings, in which elements that are the same or of the same kind are marked by the same reference numerals. It can be understood that the scale shown in the drawings is not the scale of the actual implementation of the present disclosure, and is only for illustrative purposes, and is not drawn according to the original size.

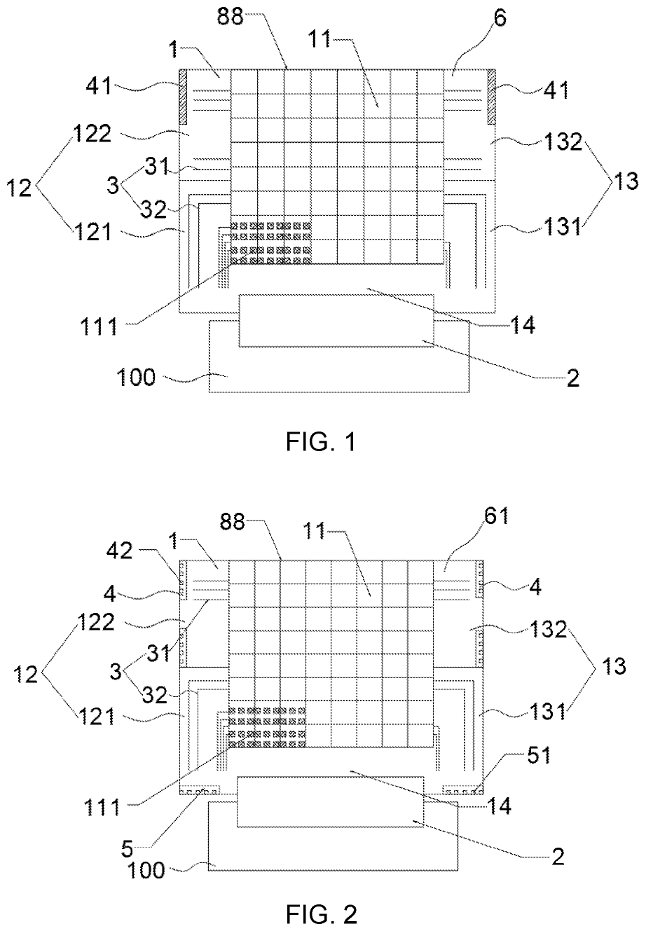

A display backplane 6 in a first embodiment is schematically shown in FIG. 1. The display backplane 6 comprises a backplane 1, a plurality of micro light-emitting diodes (micro LEDs for short) 111 arranged on the backplane 1, a plug-in circuit board 2 arranged on one end of the backplane 1, and a plurality of signal lines electrically connected to the plurality of micro LEDs 111 in a one-to-one correspondence. The backplane 1 includes a front surface 88 and a back surface (not shown) opposite to the front surface 88. The front surface 88 includes a light-emitting area 11 for mounting a plurality of light-emitting diodes, a first trace area 12 and a second trace area 13 arranged on opposite sides of the light-emitting area 11, and a third trace area 14 arranged on one side of the light-emitting area 11 and between the opposite sides (that is, the third trace area 14 is located between the first trace area 12 and the second trace area 13).

The plurality of micro LEDs 111 are in a matrix arrangement. The number of the micro LEDs 111 may be determined on the basis of the size of the micro LEDs 111 and the size of the backplane 1.

For example, when the size of a single micro LED 111 is 20 μm (i.e. micron), the distance between two adjacent micro LEDs 111 is 20 μm, the length and the width of the light-emitting area 11 at the front surface 88 are 50 cm and 32 cm respectively, and the area of the light-emitting area 11 is 1600 cm², the number of the micro LEDs 111 within the light-emitting area 11 is 40 million. When each micro LED 111 is provided with two signal lines 3, the number of the signal lines 3 is 80 million.

It should be understood that the foregoing is only an example and not a limitation.

Optionally, the plug-in circuit board 2 is arranged at one end of the third trace area 14 away from the light-emitting area 11 and electrically connected to the signal lines 3 of the micro LEDs 111. A drive circuit board 100 is connected to one end of the plug-in circuit board 2 away from the light-emitting area 11. The drive circuit board 100 is configured to control the micro LEDs 111.

Optionally, plug-in circuit board 2 is a flexible circuit board for coupling the display backplane 6 to the drive circuit board 100.

The plurality of signal lines 3 include first signal lines 31 and second signal lines 32. The first signal lines 31 are routed from the first trace area 12 and the second trace area 13 and electrically connected to the plug-in circuit board 2. The second signal lines 32 are routed along the back surface from the first trace area 12 and the second trace area in a winding manner to be arranged at the third trace area 14; further, they are routed from the third trace area 14 and electrically connected to the plug-in circuit board 2.

Optionally, the number of the signal lines may be configured on the basis of actual requirements, which is not specifically limited here.

Optionally, the areas of the first trace area 12 and the second trace area 13 are identical. For example, when the length and the width of the first trace area 12 are 32 cm and 2 cm respectively, and the length and the width of the second trace area 13 are also 32 cm and 2 cm respectively, the areas of the first trace area 12 and the second trace area 13 are both 64 cm².

It should be understood that the foregoing is only an example and not a limitation.

Optionally, the first trace area 12 includes a first sub-area 121 and a second sub-area 122. The first sub-area 121 is close to one side of the plug-in circuit board 2, and the second sub-area 122 is away from one side of the plug-in circuit board 2. The first sub-area 121 is coupled to the second sub-area 122. The second trace area 13 includes a third sub-area 131 and a fourth sub-area 132. The third sub-area 131 is close to one side of the plug-in circuit board 2, and the fourth sub-area 132 is away from one side of the plug-in circuit board 2. The third sub-area 131 is coupled to the fourth sub-area 132. Specifically, the first signal lines 31 are arranged at the first sub-area 121 and the third sub-area 131; and the second signal lines 32 are arranged at the second sub-area 122 and the fourth sub-area 132, and are wound to the back surface from the second sub-area 122 and the fourth sub-area 132.

The second sub-area 122 and the fourth sub-area 133 each are provided with a first contact 4. The first contact 4 in the second sub-area 122 and the first contact 4 in the fourth sub-area 132 are arranged away from one side of the second sub-area 122 and the fourth sub-area 132 away from light-emitting area 11. The second signal lines 32 are turned to the back surface from the first contact 4. The first sub-area 121 and the third sub-area 131 each are provided with a second contact 5 which is close to one side of the plug-in circuit board 2. The second signal lines 32 are arranged at the front surface from the back surface in a winding manner via the second contact 5.

In this embodiment, the first contact 4 is an adhesive layer 41, and the second signal lines 32 in the second sub-area 122 and the fourth sub-area 132 are configured as a golden finger coupled to the adhesive layer 41. The second signal lines 32 are turned over to the back surface through the adhesive layer 41 and are fitted into the back surface. Correspondingly, the second signal lines 32 are routed from one end of the first sub-area 121 and the third sub-area 131 which is away from the second sub-area 122 and the fourth sub-area 132 to be arranged on the front surface 88 in a winding manner and are routed to the third trace area 14 to electrically couple to the plug-in circuit board 2. The first signal lines 31 are routed to the first sub-area 121 and the third sub-area 131. The first signal lines 31 in the first sub-area 121 and the third sub-area 131 are routed to the third trace area 14 from the front surface 88, and are electrically coupled to the plug-in circuit board 2.

In this embodiment, the signal lines 32 in the second sub-area 122 and the fourth sub-area are arranged on the back surface in a winding manner, thereby reducing the trace of the second sub-area 122 and the fourth sub-area 132 on the front surface 88; on this respect, the width of the first trace area 12 as well as that of the second trace area 13 can be set smaller. Further, the border of the display backplane can be narrowed, hence improving the display effect.

Optionally, the golden finger may be, but not limited to, a material with copper as the main component. In some implementable embodiments, the golden finger may also be made of gold plating.

A display backplane 61 in a second embodiment is schematically shown in FIG. 2. The difference between the display backplane 61 of the second embodiment and the display backplane 6 of the first embodiment is that all the signal lines in the second sub-area 122 and the fourth sub-area 132 correspond to first conductive holes 42 in a one-to-one way. All the signal lines 3 in the second sub-area 122 and the fourth sub-area 132 are passed through the second contact 5 to be arranged on the back surface, and the first contact 4 includes second conductive holes 51 corresponding to the signal lines 3 on the back surface in a one-to-one way. The signal lines 3 on the back surface are passed through the second conductive holes 51 to be arranged on the front surface 88 and coupled to the third trace area 14 to be electrically connected to the plug-in circuit board 2. All the signal lines 3 of the first sub-area 121 and the third sub-area 131 are only routed from the front surface 88 to the third trace area 14 and are electrically connected to the plug-in circuit board 2.

Optionally, both the first conductive hole 42 and the second conductive hole 51 are filled with conductive material. The conductive material can be, but is not limited to, a material whose main component is metal. In some implementable embodiments, the conductive material may also be selected from a group comprising: metal elements, alloys (copper alloys, aluminum alloys, etc.), composite metals, and other special-purpose conductive materials that do not take conductivity as the main function. Commonly used conductive fillers may include nickel-coated graphite powder, nickel-coated carbon fiber carbon black, metal powder, metal foil, metal fiber, and carbon fiber. The electrical properties of conductive materials are mainly represented by electrical resistivity.

The factors that affect the electrical resistivity may include temperature, impurity content, cold deformation, heat treatment and so on. The influence of temperature may often be represented by the temperature coefficient of the resistivity of conductive materials. Except at the temperature close to the melting point and ultra-low temperature, the electrical resistivity has a linear relationship with temperature in a general temperature range.

Optionally, the first conductive holes 42 and the second conductive holes 51 may be, but not limited to, conductive holes made by etching or laser, and the first conductive holes 42 and the second conductive holes 51 are filled with conductive materials. In this respect, the front surface 88 and the back surface are electrically coupled via the first conductive holes 42 and the second conductive holes 51.

Optionally, the conductive material can be, but is not limited to, a material whose main component is metal. In some implementable embodiments, the conductive material may also be selected from a group comprising: an alloy material, a composite metal material, and a special function conductive material. The electrical properties of conductive materials are mainly represented by electrical resistivity. The factors that affect the electrical resistivity may include temperature, impurity content, cold deformation, heat treatment and so on. The influence of temperature may often be represented by the temperature coefficient of the resistivity of conductive materials. Except at the temperature close to the melting point and ultra-low temperature, the electrical resistivity has a linear relationship with temperature in a general temperature range.

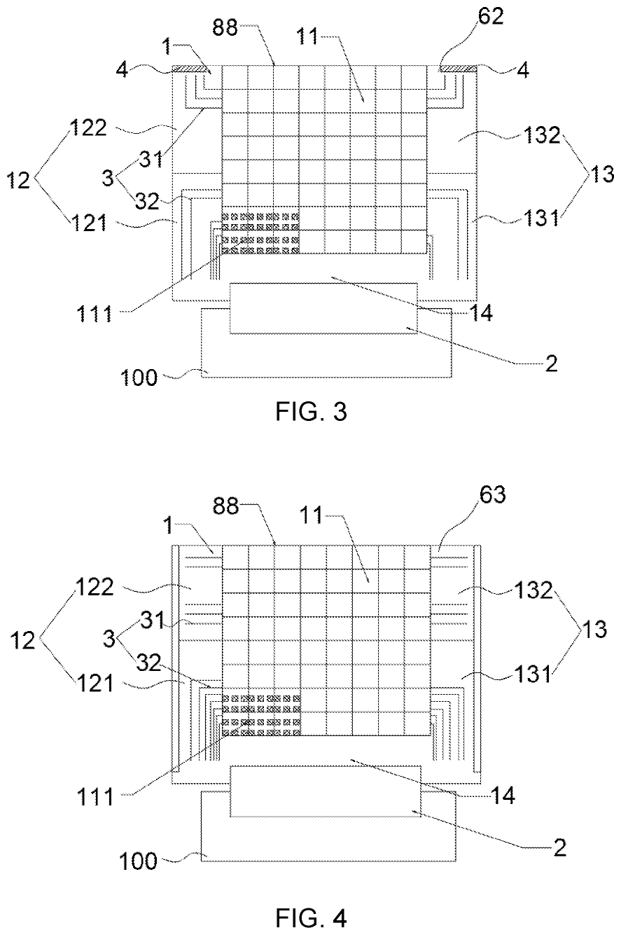

A display backplane in a third embodiment is schematically shown in FIG. 3. The difference between the display backplane of the third embodiment and the one of the first embodiment is that the second contact 5 is close to one side of the plug-in circuit board 2. The second sub-area 122 and the fourth sub-area 132 each are provided with a first contact 4; and the first contact 4 in the second sub-area 122 is arranged on a side thereof away from the first sub-area 121. The first contact 4 in the fourth sub-area 132 is arranged on a side thereof away from the third sub-area 131; and the signal lines 32 is routed to the back surface from the first contact 4. In this embodiment, the second signal lines 32 in the second sub-area 122 and the fourth sub-area 132 are routed from a side away from the plug-in circuit board 2 to be arranged on the back surface, without trace to go through the first sub-area 121 and the third sub-area 131, thereby narrowing the width of the first trace area 12 and that of the second trace area 13. Further, the border of the display backplane can be reduced, hence improving the display effect.

A display backplane 63 in a fourth embodiment is schematically shown in FIG. 4. The difference between the display backplane 63 of the fourth embodiment and the one 6 of the first embodiment is that the second signal lines 32 in the second sub-area 122 and the fourth sub-area 132 are arranged on the back surface in a winding manner; routed from one end of the first sub-area 121 and the third sub-area 131 which is away from the second sub-area 122 and the fourth sub-area 132, they are arranged on the front surface 88 in a winding manner, and are routed to the third trace area 14 to electrically coupled to the plug-in circuit board 2. The first signal lines 31 in the first sub-area 121 and the third sub-area 131 are routed to the third trace area 14 and are electrically coupled to the plug-in circuit board 2.

Optionally, both the first contact 4 and the second contact 5 are configured as an adhesive layer 41.

It should be noted that the other structures of the display backplane 63 in the fourth embodiment are similar to those in the first embodiment, which will not be repeated here.

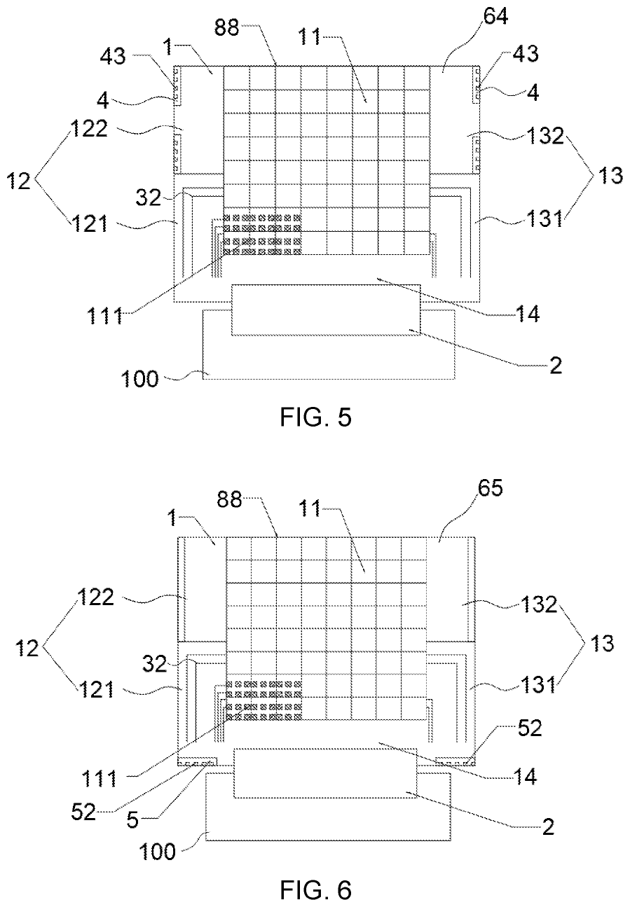

A display backplane 64 in a fifth embodiment is schematically shown in FIG. 5. The difference between the display backplane 64 of the fifth embodiment and the one 63 of the fourth embodiment is that the first contacts 4 are third conductive holes 43 corresponding to the signal lines 3 on the back surface in a one-to-one way, and the third conductive holes 43 and the first conductive hole 42 are the same. The other parts in this embodiment are similar to those in the fourth embodiment, which will not be repeated here.

A display backplane 65 in a sixth embodiment is schematically shown in FIG. 6. The difference between the display backplane 65 of the sixth embodiment and the one 63 of the fourth embodiment is that the second contacts 5 are fourth conductive holes 52 corresponding to the signal lines 3 on the back surface in a one-to-one way. The fourth conductive holes 52 are filled with conductive materials which are the same as those within the second conductive holes 51. The signal lines 3 on the back surface are passed through the fourth conductive holes 52 to be arranged on the front surface 88, and are routed to the third trace area 14 to electrically coupled to the plug-in circuit board 2.

It should be noted that the other structures of the display backplane 65 in the sixth embodiment are similar to those of the display backplane 63 in the fourth embodiment, which will not be repeated here.

Optionally, the first sub-area 121, the second sub-area 122, the third sub-area 131, and the fourth sub-area 132 have the same size; and the first sub-area 121, the second sub-area 122, the third sub-area 131, and the fourth sub-area 132 have the same number of the signal lines.

In some implementable embodiments, the number of the signal lines arranged in the second sub-area 122 and the fourth sub-area 132 may be larger than that in the first sub-area 121 and the second sub-area 122. For example, the number of the second sub-area 122 and that of the fourth sub-area 132 are equal, the number of the signal lines in the second sub-area 122 and the fourth sub-area 132 accounts for ⅔, ¾, etc. of all signal lines, which will not be limited here. In some implementable embodiments, the width of the first sub-area 121 and that of the second sub-area 122 are identical, the width of the third sub-area 131 and that of the fourth sub-area 132 are also identical but smaller than the width of the first sub-area 121 and that of the second sub-area 122. The number of the signal lines arranged in the first sub-area 121 and the third sub-area 131 accounts for ⅔, ¾, etc. of all signal lines. It can be understood that the signal lines in each area can be set according to actual conditions, and are not limited to the above examples.

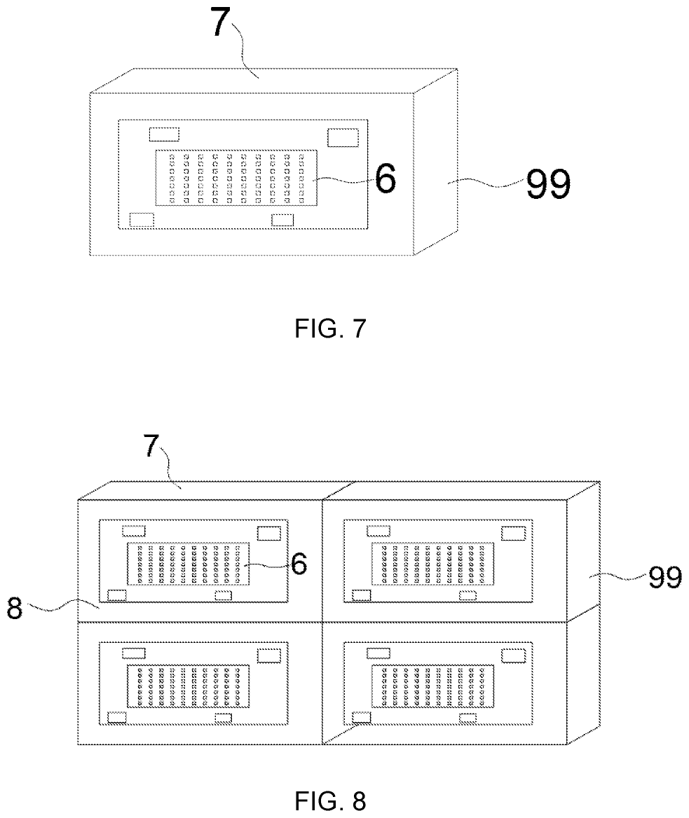

A display device 7 having the display backplane mentioned in a first embodiment is schematically shown in FIG. 7. The display device 7 includes a display backplane 6 (which may be for example the display backplane 61, the display backplane 62, the display backplane 63, the display backplane 64 and/or the display backplane 65) and a housing 99 for fixing the display backplane 6. It is understood that the display device 7 has a display function. The display device 7 may include but not limited to a monitor, a television, a computer, a notebook computer, a tablet computer, a wearable device, and the like. The above-mentioned display device 7 adopts the above-mentioned display backplane 6, and due to the trace in the display backplane 6, the utilization of the backplane 1 is improved, so that the first trace area 12 and the second trace area 13 are reduced; in this respect, the border of the display device 7 can be narrowed, without affecting the display effect.

A tiled display device 8 having the display device mentioned in a first embodiment is schematically shown in FIG. 8. The tiled display device 8 can be generated by tiling multiple display backplane 6 (which may be for example the display backplane 61, the display backplane 62, the display backplane 63, the display backplane 64 and/or the display backplane 65). In the present disclosure, the number of the display backplanes 6 in the tiled display device 8 can be two, three, four, etc., which are not limited here. The more the number of the display backplane 6 is, the larger the display area of the tiled display device 8 is. Since the tiled display device 8 uses the aforesaid the display backplane 6, the border of the display device 7 can be reduced, so that the display effect of the display device 7 is better.

Obviously, those skilled in the art can make various changes and modifications to the embodiments of the present disclosure without departing from the spirit and scope of the present disclosure. In this way, if these modifications and variations of the present disclosure fall within the scope of the claims of the present disclosure and equivalent technologies, the present disclosure is also intended to include these changes and modifications.

The above-listed are only the exemplary embodiments of the present disclosure, and of course cannot be used to limit the scope of rights of the present disclosure. Therefore, equivalent changes made in accordance with the claims of the present disclosure still fall within the scope of the present disclosure.

1. A display backplane, comprising a backplane, a plurality of micro light-emitting diodes arranged on the backplane in a matrix structure, a plug-in circuit board arranged on one end of the backplane, and a plurality of signal lines electrically connected to the plurality of micro light-emitting diodes in a one-to-one correspondence and to the plug-in circuit board, wherein the backplane comprises a front surface and a back surface opposite to the front surface; a light-emitting area provided with the plurality of micro light-emitting diodes and arranged on the front surface; a first trace area and a second trace area arranged on both opposite sides of the light-emitting area, and a third trace area arranged on one side of the light-emitting area and between the opposite sides; the third trace area is arranged between the first trace area and the second trace area; the plurality of the signal lines comprises first signal lines and second signal lines; the first signal lines are routed from the first trace area and the second trace area and are electrically coupled to the plug-in circuit board through the third trace area, the second signal lines routed along the back surface from the first trace area and the second trace area are arranged on the third trace area in a winding manner, and are routed from the third trace area and electrically coupled to the plug-in circuit board.

2. The display backplane according to claim 1, wherein the first trace area is divided into a first sub-area and a second sub-area, the first sub-area is arranged on one side of the first trace area close to the plug-in circuit board, the second sub-area is arranged on one side of the first trace area away from the plug-in circuit board; the second trace area is divided into a third sub-area and a fourth sub-area, the third sub-area is arranged on one side of the second trace area close to the plug-in circuit board; the fourth sub-area is arranged on one side of the second trace area away from the plug-in circuit board, the second signal lines are arranged in the second sub-area and the fourth sub-area and routed to the back surface in a winding manner; the first signal lines are routed from the first sub-area and the third sub-area and are electrically coupled to the plug-in circuit board through the third trace area.

3. The display backplane according to claim 2, wherein the second sub-area and the fourth sub-area each are provided with a first contact from which the second signal lines are routed to the back surface.

4. The display backplane according to claim 3, wherein the first contact is an adhesive layer arranged on one side of the second sub-area and the fourth sub-area away from the light-emitting area and configured for turning the trace of the signal lines, the signal lines correspondingly are routed from one end of the first sub-area and the third sub-area away from the second sub-area and the fourth sub-area to be arranged on the front surface in a winding manner and are routed to the third trace area.

5. The display backplane according to claim 3, wherein the first contact are a first conductive hole which is filled with a conductive material, the signal lines of the second sub-area and the fourth sub-area are routed through the first contact to be arranged on the back surface.

6. The display backplane according to claim 4, wherein the first contact is arranged on a first side of the second sub-area and the fourth sub-area away from the light-emitting area and is close to an edge of the display backplane.

7. The display backplane according to claim 4, wherein the first contact is arranged on one side of the second sub-area and the fourth sub-area away from the first sub-area and the third sub-area respectively, and is close to another edge of the backplane.

8. The display backplane according to claim 2, wherein the first sub-area and the third sub-area each are provided with a second contact, the second signal lines are routed from the back surface to be arranged on the front surface in a winding manner and are routed to the third trace area through the second contact.

9. A display device, comprising a housing and the display backplane according to claim 1 arranged in the housing.

10. A tiled display device, comprising a housing and a plurality of the display backplanes according to claim 1 arranged in the housing, the plurality of the display backplanes being tiled together.
